(19) United States
(12) Patent Application Publication
(10) Pub. No.: US 2024/0312769 A1
(43) Pub. Date: Sep. 19, 2024

(54) CERAMIC ASSEMBLY AND ELECTROSTATIC CHUCK DEVICE

(71) Applicant: SUMITOMO OSAKA CEMENT CO., LTD., Tokyo (JP)

(72) Inventors: Jun ARIKAWA, Tokyo (JP); Nobuhiro HIDAKA, Tokyo (JP); Yukio MIURA, Tokyo (JP)

(73) Assignee: SUMITOMO OSAKA CEMENT CO., LTD., Tokyo (JP)

(21) Appl. No.: 18/259,385

(22) PCT Filed: Aug. 31, 2021
(86) PCT No.: PCT/JP2021/031890

§ 371 Date: Jun. 26, 2023

(30) Foreign Application Priority Data
Dec. 28, 2020 (JP) 2020-218678

(51) Int. Cl. H01J 37/32; H01L 21/683

(52) U.S. Cl. CPC H01J 37/32715; H01J 37/32568; H01L 21/6833

(57) ABSTRACT

A ceramic joined body includes: a pair of ceramic plates; and an electrode layer and an insulating layer that are interposed between the pair of ceramic plates and, in which the insulating layer is formed of an insulating material and a conductive material.

### TECHNICAL FIELD

The present invention relates to a ceramic joined body and an electrostatic chuck device.

This application claims priority based on Japanese Patent Application No. 2020-218678 filed on Dec. 28, 2020, the content of which is incorporated herein by reference.

### BACKGROUND ART

In the related art, in a semiconductor production step of producing a semiconductor device such as IC, LSI, or VLSI, a plate-shaped sample such as a silicon wafer is fixed to an electrostatic chuck member having an electrostatic chuck function by electrostatic adsorption, and a predetermined process is performed thereon.

For example, when the plate-shaped sample is etched in a plasma atmosphere, a surface of the plate-shaped sample is heated to a high temperature by heat of the plasma, and there is a problem in that, for example, a resist film of the surface is burst.

Here, in order to maintain the temperature of the plate-shaped sample at a desired given temperature, an electrostatic chuck device having a cooling function is used. The electrostatic chuck device includes the above-described electrostatic chuck member and a base member for adjusting a temperature where a flow path that circulates a coolant for controlling a temperature to the inside of a metal member is formed. The electrostatic chuck member and the base member for adjusting a temperature are joined and integrated through a silicone adhesive on a lower surface of the electrostatic chuck member.

In this electrostatic chuck device, the coolant for adjusting a temperature is circulated for heat exchange to the flow path of the base member for adjusting a temperature such that electrostatic adsorption can be performed while maintaining the temperature of the plate-shaped sample fixed to an upper surface of the electrostatic chuck member to a desired temperature. Therefore, by using the above-described electrostatic chuck device, various plasma treatments can be performed on the plate-shaped sample while maintaining the temperature of the plate-shaped sample to be electrostatically adsorbed.

As the electrostatic chuck member, a configuration including a ceramic joined body that includes a pair of ceramic plates and an electrode layer interposed between the pair of ceramic plates is known. As a method for producing the ceramic joined body, for example, there is known a method including: forming a groove in one ceramic sintered compact; forming a conductive layer in the groove; grinding and mirror-polishing the conductive layer together with the ceramic sintered compact; and joining the one ceramic sintered compact to another ceramic sintered compact by hot press (for example refer to Patent Literature No. 1).

### CITATION LIST

### Patent Literature

[Patent Literature No. 1] Japanese Patent No. 5841329

### SUMMARY OF INVENTION

### Technical Problem

Patent Literature No. 1 indicates that fine spaces (voids) remain in an interface (joint interface) where the pair of ceramic plates are bonded, and a withstand voltage of the electrostatic chuck member may decrease, that is, breakdown may occur due to this mechanism. In the electrostatic chuck member including the voids, when a high voltage is applied to a dielectric layer (ceramic plate), it is expected that charges accumulate in the voids and are discharged such that breakdown occurs in the ceramic plate.

However, in the method described in Patent Literature No. 1, the formation of voids between the electrode layer and the ceramic plate cannot be sufficiently suppressed. Therefore, in the ceramic joined body described in Patent Literature No. 1, breakdown of a ceramic plate caused by discharge cannot be sufficiently prevented, and improvement is required.

The present invention has been made in consideration of the above-described circumstances, and an object thereof is to provide a ceramic joined body where the occurrence of breakdown in a ceramic plate caused by discharge is suppressed when a high voltage is applied, and an electrostatic chuck device including the ceramic joined body.

### Solution to Problem

In order to achieve the above-described object, the present invention includes the following aspects.
[1] A ceramic joined body includes:
a pair of ceramic plates;
an electrode layer that is interposed between the pair of ceramic plates; and
an insulating layer that is disposed in a periphery of the electrode layer between the pair of ceramic plates,
in which the insulating layer is formed of an insulating material and a conductive material.
[2] The ceramic joined body according to [1],
in which the insulating layer is a layer which has been integrally formed with one of the pair of ceramic plates.
[3] The ceramic joined body according to [1] or [2],
in which the insulating material is at least one selected from the group consisting of Al₂O₃, AlN, Si₃N₄, Y₂O₃, YAG, SmAlO₃, MgO, and SiO₂.
[4] The ceramic joined body according to any one of [1] to [3],
in which the conductive material is at least one selected from the group consisting of SiC, TiO₂, TiN, TiC, W, WC, Mo, Mo₂C, and C.
[5] The ceramic joined body according to any one of [1] to [4],
in which a relative density of an outer edge of the electrode layer is lower than a relative density of a center of the electrode layer.
[6] The ceramic joined body according to any one of [1] to [5],
in which materials of the pair of ceramic plates are the same as each other.
[7] The ceramic joined body according to any one of [1] to [6],
in which the pair of ceramic plates are formed of an insulating material and a conductive material.
[8] An electrostatic chuck device,
in which an electrostatic chuck member, which is formed of a ceramic, and a base member for adjusting a temperature, which is formed of a metal, are joined through an adhesive layer, and
the electrostatic chuck member is formed of the ceramic joined body according to any one of [1] to [7].

### Advantageous Effects of Invention

According to the present invention, it is possible to provide a ceramic joined body where the occurrence of breakdown in a ceramic plate caused by discharge is suppressed when a high voltage is applied, and an electrostatic chuck device including the ceramic joined body.

### BRIEF DESCRIPTION OF DRAWINGS

FIG. 1 is a cross-sectional view showing a ceramic joined body according to one embodiment of the present invention.

FIG. 2 is a cross-sectional view showing a ceramic joined body according to an embodiment of the present invention.

FIG. 3 is a cross-sectional view showing a ceramic joined body according to an embodiment of the present invention.

FIG. 4 is a cross-sectional view showing an electrostatic chuck device according to one embodiment of the present invention.

### DESCRIPTION OF EMBODIMENTS

Embodiments of a ceramic joined body and an electrostatic chuck device according to the present invention will be described.

The embodiments will be described in detail for easy understanding of the concept of the present invention, but the present invention is not limited thereto unless specified otherwise.

### [Ceramic Joined Body]

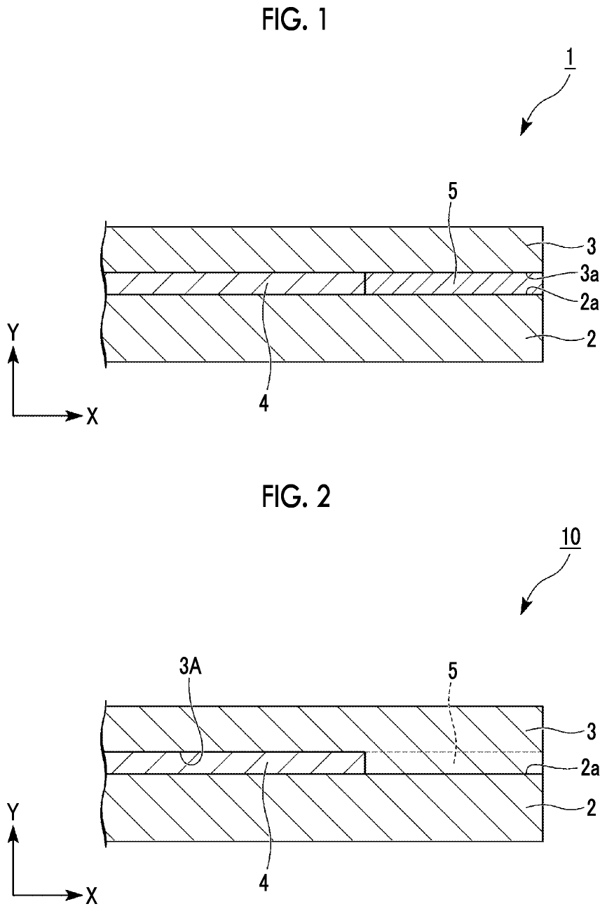

Hereinafter, a ceramic joined body according to one embodiment of the present invention will be described with reference to FIG. 1. In FIG. 1, note that a horizontal direction of the paper plane (width direction of the ceramic joined body) is an X direction and a vertical direction of the paper plane (thickness direction of the ceramic joined body) is a Y direction.

In all of the following drawings, dimensions, ratios, and the like of the components may be appropriately different from the actual ones in order to easily understand the drawings.

FIG. 1 is a cross-sectional view showing the ceramic joined body according to the embodiment. As shown in FIG. 1, the ceramic joined body 1 according to the embodiment includes: a pair of ceramic plates 2 and 3; and an electrode layer 4 and an insulating layer 5 that are interposed between the pair of ceramic plates 2 and 3.

When a minimum circle among circles circumscribing the ceramic joined body 1 in a plan view is assumed, the cross-sectional view shown in FIG. 1 is a cross-section of the ceramic joined body taken along a virtual plane including the center of the circle. When the ceramic joined body 1 is substantially circular in a plan view, the center of the circle and the center of the shape of the ceramic joined body in a plan view substantially match each other.

In the present specification, “plan view” refers to a view seen from the Y direction that is the thickness direction of the ceramic joined body.

In addition, in the present specification, “outer edge” refers to a region in the vicinity of an outer periphery of an object in a plan view.

Hereinafter, the ceramic plate 2 will be referred to as the first ceramic plate 2, and the ceramic plate 3 will be referred to as the second ceramic plate 3.

As shown in FIG. 1, in the ceramic joined body 1, the first ceramic plate 2, the electrode layer 4 and the insulating layer 5, and the second ceramic plate 3 are laminated in this order. That is, the ceramic joined body 1 is a joined body where the first ceramic plate 2 and the second ceramic plate 3 are joined and integrated through the electrode layer 4 and the insulating layer 5. In addition, the electrode layer 4 and the insulating layer 5 are provided in contact with a joint surface 2a of the first ceramic plate 2 facing the second ceramic plate 3 and a joint surface 3a of the second ceramic plate 3 facing the first ceramic plate 2.

In the ceramic joined body 1 according to the embodiment, the insulating layer 5 is formed of an insulating material and a conductive material.

### (Ceramic Plate)

Shapes of outer peripheries of overlapping surfaces of the first ceramic plate 2 and the second ceramic plate 3 are made the same.

The thicknesses of the first ceramic plate 2 and the second ceramic plate 3 are not particularly limited and can be appropriately adjusted depending on the use of the ceramic joined body 1.

The first ceramic plate 2 and the second ceramic plate 3 have the same composition or the same major component. The first ceramic plate 2 and the second ceramic plate 3 are formed of a composite body of an insulating material and a conductive material.

The insulating material in the first ceramic plate 2 and the second ceramic plate 3 is not particularly limited, and examples thereof include aluminum oxide (Al₂O₃), aluminum nitride (AlN), yttrium oxide (Y₂O₃), and yttrium-aluminum-garnet (YAG). In particular, Al₂O₃ or AlN is preferable.

The conductive material in the first ceramic plate 2 and the second ceramic plate 3 is not particularly limited, and examples thereof include silicon carbide (SiC), titanium oxide (TiO₂), titanium nitride (TiN), titanium carbide (TiC), a carbon material, rare earth oxide, and rare earth fluoride. Examples of the carbon material include carbon nanotubes (CNT) and carbon nanofibers. In particular, SiC is preferable.

The material of the first ceramic plate 2 and the second ceramic plate 3 is not particularly limited as long as it has a volume specific resistance value of about 10¹³ Ω·cm or more and 10¹⁷ Ω·cm or less, has a mechanical strength, and has durability to corrosive gas and plasma thereof. Examples of the material include an Al₂O₃ sintered compact, an AlN sintered compact, and an Al₂O₃—SiC composite sintered compact. From the viewpoints of dielectric characteristics, high corrosion resistance, plasma resistance, and heat resistance at a high temperature, it is preferable that the material of the first ceramic plate 2 and the second ceramic plate 3 is an Al₂O₃—SiC composite sintered compact.

The average primary particle diameter of the insulating material forming the first ceramic plate 2 and the second ceramic plate 3 is preferably 0.5 μm or more and 3.0 μm or less, more preferably 0.7 μm or more and 2.0 μm or less, and still more preferably 1.0 μm or more and 2.0 μm or less.

When the average primary particle diameter of the insulating material forming the first ceramic plate 2 and the second ceramic plate 3 is 0.5 μm or more and 3.0 μm or less, the first ceramic plate 2 and the second ceramic plate 3 that are dense, have high voltage endurance, and have high durability can be obtained.

A method of measuring the average primary particle diameter of the insulating material forming the first ceramic plate 2 and the second ceramic plate 3 is as follows. Using a field emission scanning electron microscope (FE-SEM; manufactured by JEOL Ltd., JSM-7800F-Prime), a cut surface of the first ceramic plate 2 and the second ceramic plate 3 in the thickness direction was observed at a magnification of 10000-fold, and the average particle diameter of 200 particles of the insulating material was obtained as the average primary particle diameter using an intercept method.

### (Electrode Layer)

The electrode layer 4 is configured to be used as, for example, an electrode for plasma generation that applies high frequency power to generate plasma for a plasma treatment, an electrode for an electrostatic chuck that generates charges and fixes a plate-shaped sample due to an electrostatic adsorption force, or a heater electrode that heats a plate-shaped sample by electric heating. The shape of the electrode layer 4 (the shape of the electrode layer 4 when seen in a plan view) or the size thereof (the thickness or the area of the electrode layer 4 when seen in a plan view) is not particularly limited and is appropriately adjusted depending on the use of the ceramic joined body 1.

The electrode layer 4 is formed of a sintered compact of particles of a conductive material or a composite body (sintered compact) of particles of an insulating ceramic and particles of a conductive material.

In addition, the electrode layer 4 is a thin electrode that is wider in a direction perpendicular to the thickness direction than in the thickness direction. For example, the electrode layer 4 has a disk shape having a thickness of 20 μm and a diameter of 29 cm. As described below, the electrode layer 4 can be formed by applying and sintering a paste for forming an electrode layer. The paste for forming an electrode layer is likely to isotropically shrink by sintering during volume shrinkage. Therefore, the shrinkage amount in the direction perpendicular to the thickness direction is more than that in the thickness direction. Therefore, voids are likely to be structurally formed in the outer edge of the electrode layer 4, that is, the interface between the electrode layer 4 and the insulating layer 5.

In the present specification, the term “void” refers to a space having a major axis length of less than 50 μm that is formed at an interface between a first ceramic plate and the electrode layer or at an interface between a second ceramic plate and the electrode layer.

When the electrode layer 4 is formed of the insulating ceramic and the conductive material, a volume specific resistance value of a mixed material of the insulating ceramic and the conductive material is preferably about 10⁻⁶ Ω·cm or more and 10⁻² Ω·cm or less.

When the electrode layer 4 is formed of a composite body of the insulating ceramic and the conductive material, the content of the conductive material in the electrode layer 4 is preferably 15% by mass or more and 100% by mass or less and more preferably 20% by mass or more and 100% by mass or less. When the content of the conductive material is the lower limit value or more, sufficient dielectric characteristics can be exhibited in the ceramic plate 3.

The conductive material in the electrode layer 4 may be a conductive ceramic or a conductive material such as a metal or a carbon material. The conductive ceramic (conductive material) in the electrode layer 4 is preferably at least one selected from the group consisting of SiC, TiO₂, TiN, TiC, tungsten (W), tungsten carbide (WC), molybdenum (Mo), molybdenum carbide (Mo₂C), tantalum (Ta), tantalum carbide (TaC, Ta₄C₅), a carbon material, and a conductive composite sintered compact.

Examples of the carbon material include carbon black, carbon nanotubes, and carbon nanofibers.

Examples of the conductive composite sintered compact include Al₂O₃—Ta₄C₅, Al₂O₃—W, Al₂O₃—SiC, AlN—W, and AlN—Ta.

The conductive material in the electrode layer 4 is formed of at least one selected from the group consisting of the above-described materials such that the conductivity of the electrode layer can be secured.

The insulating ceramic in the electrode layer 4 is not particularly limited and is preferably, for example, at least one selected from the group consisting of Al₂O₃, AlN, silicon nitride (Si₃N₄), Y₂O₃, YAG, samarium-aluminum oxide (SmAlO₃), magnesium oxide (MgO), and silicon oxide (SiO₂).

The electrode layer 4 is formed of the conductive material and the insulating material, and the joint strength of the first ceramic plate 2 and the second ceramic plate 3 and the mechanical strength as an electrode are strong.

The insulating material in the electrode layer 4 is Al₂O₃ such that dielectric characteristics, high corrosion resistance, plasma resistance, and heat resistance at a high temperature are maintained.

A ratio (mixing ratio) between the contents of the conductive material and the insulating material in the electrode layer 4 is not particularly limited and is appropriately adjusted depending on the use of the ceramic joined body 1.

The electrode layer 4 may have the same relative density as a whole. In addition, the density of the electrode layer 4 in the outer edge may be lower than that at the center of the electrode layer 4. The density (relative density) of the electrode layer 4 is obtained from a microscope image of the cross-section of the ceramic joined body 1.

### (Method of Measuring Relative Density of Electrode Layer)

Specifically, the cross-section shown in FIG. 1 is imaged using a microscope (for example, a digital microscope (VFX-900F), manufactured by Keyence Corporation) at a magnification of 1000-fold to obtain a microscope image. When the relative density of the outer edge of the electrode layer 4 is measured, an imaging range is the electrode layer 4 in a range of 150 μm from an end portion of the electrode layer 4 in the X direction (for example, an end portion in the +X direction) toward an inner side (for example, −X direction) of the electrode layer 4 in the X direction. Hereinafter, the electrode layer 4 in the range will be referred to as “density measurement region”.

In the microscope image, in a virtual plane overlapping the cross-section of the electrode layer 4, a region (a region where the material is present; a region 1) where the conductive ceramic and the insulating ceramic forming the electrode layer 4 are present and a “pore” region (a region 2) where both of the conductive ceramic and the insulating ceramic are not present can be distinguished from each other.

The relative density of the outer edge of the electrode layer 4 is a value obtained by expressing the area of a portion within an outer contour of the density measurement region, that is, a ratio of the area of the region 1 to the total area of the region 1 and the region 2 in percentage. When pores are not present in the electrode layer 4, the relative density of the density measurement region is 100%.

In addition, when the relative density of the center of the electrode layer 4 is measured, the imaging range is a region (center) including the center of the electrode layer 4 in the X direction. When it can be determined from the microscope image that the imaging range has the same density as that of the center of the electrode layer 4, the imaging range does not need to include the center of the electrode layer 4 to be exact.

In the obtained microscope image, by setting the electrode layer 4 in the range of 150 μm in the X direction as “density measurement region” and performing the calculation using the same method as that of the density of the outer edge of the electrode layer 4, the relative density of the center of the electrode layer 4 can be obtained.

By comparing the relative densities obtained as described above to each other, whether or not the outer edge of the electrode layer 4 has a lower density than the center of the electrode layer 4 can be determined.

When the outer edge of the electrode layer 4 has a lower density, the relative density of the outer edge of the electrode layer 4 is preferably 50% or more and more preferably 55% or more. When the relative density of the outer edge of the electrode layer 4 is less than 50%, resistance heating is more likely to occur as compared to a case where the outer edge of the electrode layer 4 has a higher density, and in-plane temperature uniformity during application of high frequency power is likely to deteriorate. On the other hand, in the ceramic joined body where the relative density of the outer edge of the electrode layer 4 is 50% or more, in-plane temperature uniformity during application of high frequency power is maintained.

For example, a region where the relative density of the electrode layer 4 is 100% includes the center in the X direction and accounts for 95% or more with respect to the total width, and a region where the relative density of the electrode layer 4 is lower than that of the center accounts for 5% or less in total including 2.5% from each of opposite end portions in the X direction.

### (Insulating Layer)

The insulating layer 5 is configured to be provided for joining boundary portions of the first ceramic plate 2 and the second ceramic plate 3, that is, outer edge regions other than a portion where the electrode layer 4 is formed. The insulating layer 5 is disposed in the periphery of the electrode layer 4 in a plan view between the first ceramic plate 2 and the second ceramic plate 3 (between the pair of ceramic plates).

The shape of the insulating layer 5 (the shape of the insulating layer 5 when seen in a plan view) is not particularly limited and is appropriately adjusted depending on the shape of the electrode layer 4.

The thickness of the insulating layer 5 (the width in the Y direction) is the same as the thickness of the electrode layer 4.

The insulating layer 5 is formed of a compound material including an insulating material and a conductive material. The volume specific resistance value of the insulating layer 5 is 10¹³ Ω·cm or more and 10¹⁷ Ω·cm or less.

The insulating material forming the insulating layer 5 is not particularly limited and is preferably the same as a major component of the first ceramic plate 2 and the second ceramic plate 3. The insulating material forming the insulating layer 5 is, for example, preferably at least one selected from the group consisting of Al₂O₃, AlN, Si₃N₄, Y₂O₃, YAG, SmAlO₃, MgO, and SiO₂. The insulating material forming the insulating layer 5 is preferably Al₂O₃. The insulating material forming the insulating layer 5 is Al₂O₃ such that dielectric characteristics, high corrosion resistance, plasma resistance, and heat resistance at a high temperature are maintained.

The conductive material forming the insulating layer 5 is not particularly limited and is preferably the same as a major component of the first ceramic plate 2 and the second ceramic plate 3. The conductive material forming the insulating layer 5 is, for example, preferably at least one selected from the group consisting of SiC, TiO₂, TiN, TiC, W, WC, Mo, Mo₂C, and a carbon material. Examples of the carbon material include carbon nanotubes and carbon nanofibers. The conductive material forming the insulating layer 5 is preferably SiC.

The content of the insulating material in the insulating layer 5 is preferably 80% by mass or more and 96% by mass or less, more preferably 80% by mass or more and 95% by mass or less, and still more preferably 85% by mass or more and 95% by mass or less. When the content of the insulating material is the lower limit value or more, sufficient voltage endurance can be obtained. When the content of the insulating material is the upper limit value or less, the static elimination effect of the conductive material in the insulating layer 5 can be sufficiently exhibited.

The content of the conductive material in the insulating layer 5 is preferably 4% by mass or more and 20% by mass or less, more preferably 5% by mass or more and 20% by mass or less, and still more preferably 5% by mass or more and 15% by mass or less. When the content of the conductive material is the lower limit value or more, the static elimination effect of the conductive material can be sufficiently exhibited. When the content of the conductive material is the upper limit value or less, a sufficient withstand voltage can be obtained.

The average primary particle diameter of the insulating material forming the insulating layer 5 is preferably 0.5 μm or more and 3.0 μm or less and more preferably 0.7 μm or more and 2.0 μm or less.

When the average primary particle diameter of the insulating material forming the insulating layer 5 is 0.5 μm or more, sufficient voltage endurance can be obtained. On the other hand, when the average primary particle diameter of the insulating material forming the insulating layer 5 is 3.0 μm or less, processing such as grinding is simple.

The average primary particle diameter of the conductive material forming the insulating layer 5 is preferably 0.1 μm or more and 1.0 μm or less and more preferably 0.1 μm or more and 0.8 μm or less.

When the average primary particle diameter of the conductive material forming the insulating layer 5 is 0.1 μm or more, sufficient voltage endurance can be obtained. On the other hand, when the average primary particle diameter of the conductive material forming the insulating layer 5 is 1.0 μm or less, processing such as grinding is simple.

A method for measuring the average primary particle diameters of the insulating material and the conductive material forming the insulating layer 5 is the same as the method for measuring the average primary particle diameters of the insulating material and the conductive material forming the first ceramic plate 2 and the second ceramic plate 3.

In the ceramic joined body 1 according to the embodiment, charges in the ceramic joined body 1 can be eliminated from the ceramic plates 2 and 3 formed of the insulating material and the conductive material. Further, as described above, in the ceramic joined body 1, voids are likely to be formed in an outer edge of the electrode layer, and the formed voids are likely to be charged. However, the insulating layer 5 is formed of the insulating material and the conductive material. Therefore, when a high voltage is applied to the ceramic joined body 1, charges in a joint interface between the electrode layer 4 and the insulating layer 5 can be eliminated by the insulating layer 5. As a result, charging of the joint interface between the electrode layer 4 and the insulating layer 5 can be suppressed, and breakdown of the ceramic joined body 1 caused by discharge can be suppressed.

### Other Embodiments

The present invention is not limited to the above-described embodiment.

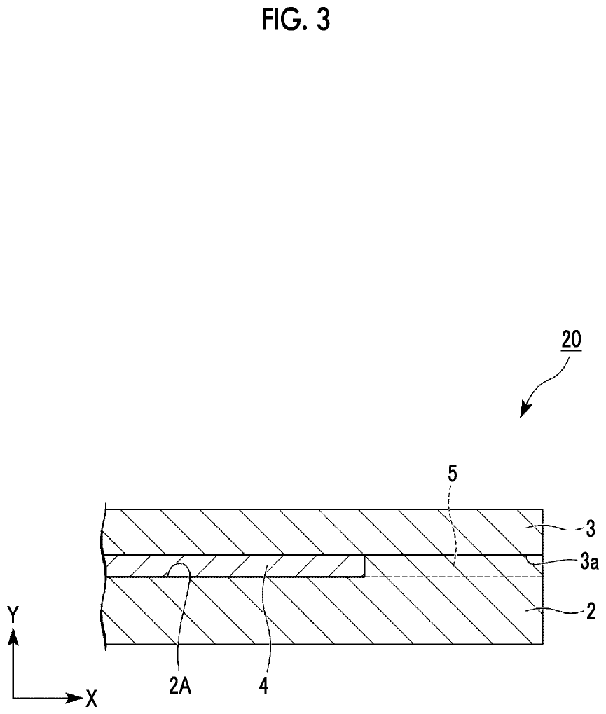

For example, modification examples shown in FIGS. 2 and 3 may be adopted. In the modification examples, the same portions as the components in the embodiment will be represented by the same reference numerals, the description thereof will not be repeated, and only different points will be described.

### Modification Example 1

In a ceramic joined body 10 according to a modification example shown in FIG. 2, the insulating layer 5 is integrally formed with the second ceramic plate 3. In the present specification, “being integrally formed with” represents being formed as one member (being one member). This representation is different from the configuration of the second ceramic plate 3 and the insulating layer 5 according to the modification example where two separate members are “integrated” into one member.

The insulating layer 5 is formed of the same material as the second ceramic plate 3. The second ceramic plate 3 has a recess portion 3A, and the insulating layer 5 is provided in an annular shape in the periphery of the recess portion 3A. A part of the second ceramic plate 3 corresponds to the insulating layer 5. The recess portion 3A can be formed by grinding or polishing a ceramic plate having no recess portion.

In the ceramic joined body 10, charges in the joint interface between the electrode layer 4 and the insulating layer 5 can be eliminated not only by the ceramic plate 2 and the ceramic plate 3 but also the insulating layer 5. As a result, charging of the joint interface between the electrode layer 4 and the insulating layer 5 can be suppressed, and breakdown of the ceramic joined body 10 caused by discharge can be suppressed.

### Modification Example 2

In a ceramic joined body 20 according to a modification example shown in FIG. 3, the insulating layer 5 is integrally formed with the first ceramic plate 2. The insulating layer 5 is formed of the same material as the first ceramic plate 2. The first ceramic plate 2 has a recess portion 2A, and the insulating layer 5 is provided in an annular shape in the periphery of the recess portion 2A. A part of the first ceramic plate 2 corresponds to the insulating layer 5. The recess portion 2A can be formed by grinding or polishing a ceramic plate having no recess portion.

An inner surface of the recess portion 2A may be parallel to the Y direction and may have an inclination with respect to the Y direction. When the inner surface has an inclination with respect to the Y direction, an opening diameter of the recess portion 2A decreases in a depth direction of the recess portion 2A.

In the ceramic joined body 20, charges in the joint interface between the electrode layer 4 and the insulating layer 5 can be eliminated not only by the ceramic plate 2 and the ceramic plate 3 but also the insulating layer 5. As a result, charging of the joint interface between the electrode layer 4 and the insulating layer 5 can be suppressed, and breakdown of the ceramic joined body 20 caused by discharge can be suppressed.

### [Method for Producing Ceramic Joined Body]

A method for producing the ceramic joined body according to the embodiment includes: a step (hereinafter, referred to as “first step”) of applying a paste for forming an electrode layer to one surface of the first ceramic plate to form an electrode layer coating film and applying a paste for forming an insulating layer to the ground or polished surface to form an insulating layer coating film; a step (hereinafter, referred to as “second step”) of laminating the pair of ceramic plates in a posture in which the surface where the electrode layer coating film and the insulating layer coating film are formed faces inward; and a step (hereinafter, referred to as “third step”) of pressurizing the laminate including the pair of ceramic plates, the electrode layer coating film, and the insulating layer coating film in a thickness direction while heating the laminate.

Hereinafter, the method for producing the ceramic joined body according to the embodiment will be described with reference to FIG. 1.

In the first step, using a coating method such as a screen printing method, the paste for forming an electrode layer is applied to, for example, the surface 2a of the first ceramic plate 2 to form a coating film (electrode layer coating film) for forming the electrode layer 4.

As the paste for forming an electrode layer, a dispersion liquid in which particles of the conductive material or particles of the conductive material and the insulating material for forming the electrode layer 4 are dispersed in a solvent is used.

In addition, in the first step, the paste for forming an insulating layer is applied using a coating method such as a screen printing method to the polished surface 2a of the first ceramic plate 2 to form a coating film (insulating layer coating film) for forming the insulating layer 5.

As the paste for forming an insulating layer, a dispersion liquid in which the insulating material and the conductive material for forming the insulating layer 5 are dispersed in a solvent is used.

As the solvent in the paste for forming an insulating layer, for example, isopropyl alcohol is used.

In the second step, the first ceramic plate 2 is laminated on the joint surface 3a of the second ceramic plate 3 in a posture in which the surface where the electrode layer coating film and the insulating layer coating film are formed faces inward.

In the third step, the laminate including the first ceramic plate 2, the electrode layer coating film, the insulating layer coating film, and the second ceramic plate 3 is pressurized in the thickness direction while being heated.

The atmosphere in which the laminate is pressurized in the thickness direction while being heated is preferably a vacuum or an inert atmosphere such as Ar, He, or N₂.

A temperature (heat treatment temperature) at which the laminate is heated is preferably 1400° C. or higher and 1900° C. or lower and more preferably 1500° C. or higher and 1850° C. or lower.

When the temperature at which the laminate is heated is 1400° C. or higher and 1900° C. or lower, the solvent in each of the coating films is volatilized such that the electrode layer 4 can be formed between the first ceramic plate 2 and the second ceramic plate 3. In addition, the first ceramic plate 2 and the second ceramic plate 3 can be joined and integrated through the electrode layer 4.

The pressure (welding pressure) at which the laminate is pressurized in the thickness direction is preferably 1.0 MPa or more and 50.0 MPa or less and more preferably 5.0 MPa or more and 20.0 MPa or less.

When the pressure at which the laminate is pressurized in the thickness direction is 1.0 MPa or more and 50.0 MPa or less, the electrode layer 4 and the insulating layer 5 can be formed between the first ceramic plate 2 and the second ceramic plate 3. In addition, the first ceramic plate 2 and the second ceramic plate 3 can be joined and integrated through the electrode layer 4 and the insulating layer 5.

With the method for producing the ceramic joined body according to the embodiment, the ceramic joined body 1 where the insulating layer 5 is formed of the insulating material and the conductive material can be provided. In the obtained ceramic joined body 1, when a high voltage is applied, discharge in the joint interface between the first and second ceramic plates 2 and 3 and the insulating layer 5 can be suppressed, and breakdown caused by discharge can be suppressed.

### [Electrostatic Chuck Device]

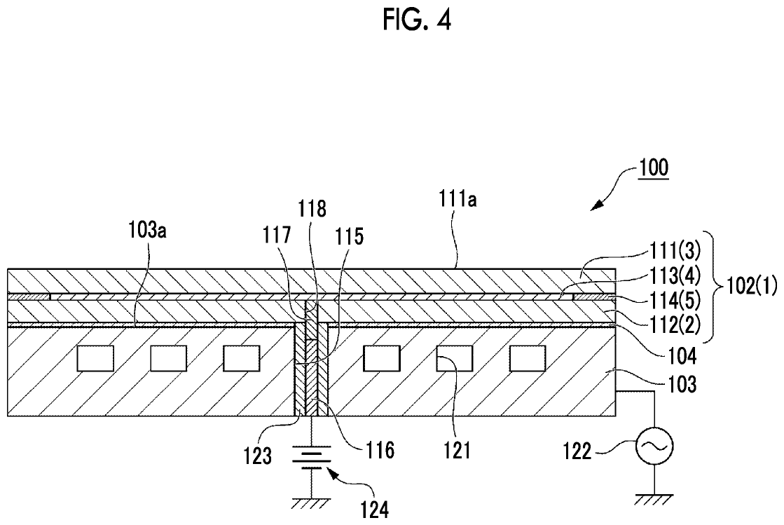

Hereinafter, an electrostatic chuck device according to an embodiment of the present invention will be described with reference to FIG. 4.

FIG. 4 is a cross-sectional view showing the electrostatic chuck device according to the embodiment. In FIG. 4, the same components as those of the ceramic joined body shown in FIG. 1 are represented by the same reference numerals, and the repeated description thereof will not be repeated.

As shown in FIG. 4, an electrostatic chuck device 100 according to the embodiment includes: a disk-shaped electrostatic chuck member 102; a disk-shaped base member 103 for adjusting a temperature that adjusts the electrostatic chuck member 102 to a desired temperature; and an adhesive layer 104 that joins and integrates the electrostatic chuck member 102 and the base member 103 for adjusting a temperature. In the electrostatic chuck device 100 according to the embodiment, the electrostatic chuck member 102 is, for example, the ceramic joined body 1 according to the embodiment. Here, a case where the electrostatic chuck member 102 is the ceramic joined body 1 will be described.

In the following description, a placement surface 111a side of a placement plate 111 is set as “upper side” and the base member 103 side for adjusting a temperature is set as “lower side” to represent relative positions of the components.

### [Electrostatic Chuck Member]

The electrostatic chuck member 102 includes: a placement plate 111 that is formed of a ceramic and has, as an upper surface, the placement surface 111a on which a plate-shaped sample such as a semiconductor wafer is placed; a supporting plate 112 that is provided on a surface side of the placement plate 111 opposite to the placement surface 111a; an electrode 113 for electrostatic adsorption that is interposed between the placement plate 111 and the supporting plate 112; an annular insulating material 114 that surrounds the periphery of the electrode 113 for electrostatic adsorption interposed between the placement plate 111 and the supporting plate 112; and a power feeding terminal 116 that is provided in a fixing hole 115 of the base member 103 for adjusting a temperature to be in contact with the electrode 113 for electrostatic adsorption.

In the electrostatic chuck member 102, the placement plate 111 corresponds to the second ceramic plate 3, the supporting plate 112 corresponds to the first ceramic plate 2, the electrode 113 for electrostatic adsorption corresponds to the electrode layer 4, and the insulating material 114 corresponds to the insulating layer 5.

### [Placement Plate]

On the placement surface 111a of the placement plate 111, a plurality of protrusions for supporting the plate-shaped sample such as a semiconductor wafer are formed (not shown). Further, in order to prevent leakage of cold gas such as helium (He) in a peripheral portion of the placement surface 111a of the placement plate 111, an annular protrusion having a square shape in cross-section may be provided to surround the peripheral portion. Further, in a region around the annular protrusion on the placement surface 111a, a plurality of protrusions that have the same height as the annular protrusion, have a circular shape in cross-section, and have a substantially rectangular shape in vertical section may be provided.

The thickness of the placement plate 111 is preferably 0.3 mm or more and 3.0 mm or less and more preferably 0.5 mm or more and 1.5 mm or less. When the thickness of the placement plate 111 is 0.3 mm or more, voltage endurance is excellent. On the other hand, when the thickness of the placement plate 111 is 3.0 mm or less, the electrostatic adsorption force of the electrostatic chuck member 102 does not decrease, thermal conductivity between the plate-shaped sample placed on the placement surface 111a of the placement plate 111 and the base member 103 for adjusting a temperature does not deteriorate, and the temperature of the plate-shaped sample that is being processed can be maintained at a given preferable temperature.

### [Supporting Plate]

The supporting plate 112 supports the placement plate 111 and the electrode 113 for electrostatic adsorption from the lower side.

The thickness of the supporting plate 112 is preferably 0.3 mm or more and 3.0 mm or less and more preferably 0.5 mm or more and 1.5 mm or less. When the thickness of the supporting plate 112 is 0.3 mm or more, a sufficient withstand voltage can be secured. On the other hand, when the thickness of the supporting plate 112 is 3.0 mm or less, the electrostatic adsorption force of the electrostatic chuck member 102 does not decrease, thermal conductivity between the plate-shaped sample placed on the placement surface 111a of the placement plate 111 and the base member 103 for adjusting a temperature does not deteriorate, and the temperature of the plate-shaped sample that is being processed can be maintained at a given preferable temperature.

### [Electrode for Electrostatic Adsorption]

In the electrode 113 for electrostatic adsorption, by applying a voltage, the electrostatic adsorption force with which the plate-shaped sample is supported on the placement surface 111a of the placement plate 111 is generated.

The thickness of the electrode 113 for electrostatic adsorption is preferably 5 μm or more and 200 μm or less and more preferably 10 μm or more and 100 μm or less. When the thickness of the electrode 113 for electrostatic adsorption is 5 μm or more, sufficient conductivity can be secured. On the other hand, when the thickness of the electrode 113 for electrostatic adsorption is 200 μm or less, thermal conductivity between the plate-shaped sample placed on the placement surface 111a of the placement plate 111 and the base member 103 for adjusting a temperature does not deteriorate, and the temperature of the plate-shaped sample that is being processed can be maintained at a given desirable temperature. In addition, plasma permeability does not deteriorate, and plasma can be stably generated.

### [Insulating Material]

The insulating material 114 is a member that surrounds the electrode 113 for electrostatic adsorption to protect the electrode 113 for electrostatic adsorption from corrosive gas and plasma thereof.

Due to the insulating material 114, the placement plate 111 and the supporting plate 112 are joined and integrated through the electrode 113 for electrostatic adsorption.

### [Power Feeding Terminal]

The power feeding terminal 116 is a member that applies a voltage to the electrode 113 for electrostatic adsorption.

The number, the shape, and the like of the power feeding terminals 116 are determined depending on the form of the electrode 113 for electrostatic adsorption, that is, whether the electrode 113 for electrostatic adsorption is unipolar or bipolar.

The material of the power feeding terminal 116 is not particularly limited as long as it is a conductive material having excellent heat resistance. As the material of the power feeding terminal 116, a material having a thermal expansion coefficient similar to those of the electrode 113 for electrostatic adsorption and the supporting plate 112 is preferable. For example, a metal material such as a cobalt alloy or niobium (Nb) and various conductive ceramics are preferably used.

### [Conductive Adhesive Layer]

A conductive adhesive layer 117 is provided in the fixing hole 115 of the base member 103 for adjusting a temperature and in a through hole 118 of the supporting plate 112. In addition, the conductive adhesive layer 117 is interposed between the electrode 113 for electrostatic adsorption and the power feeding terminal 116 and electrically connects the electrode 113 for electrostatic adsorption and the power feeding terminal 116 to each other.

A conductive adhesive forming the conductive adhesive layer 117 includes a conductive material such as carbon fibers or metal powder and a resin.

The resin in the conductive adhesive is not particularly limited as long as it suppresses the occurrence of cohesive failure caused by thermal stress. Examples of the resin include a silicone resin, an acrylic resin, an epoxy resin, a phenol resin, a polyurethane resin, and an unsaturated polyester resin.

Among these, a silicone resin is preferable from the viewpoints that the degree of expansion and contraction is high and cohesive failure caused by a change in thermal stress is not likely to occur.

### [Base Member for Adjusting Temperature]

The base member 103 for adjusting a temperature is a disk-shaped thick member formed of at least one of a metal or a ceramic. The body of the base member 103 for adjusting a temperature is configured to function as an internal electrode for generating a plasma. In the body of the base member 103 for adjusting a temperature, a flow path 121 for circulating a coolant such as water, He gas, or N₂ gas is formed.

The body of the base member 103 for adjusting a temperature is connected to an external high frequency power supply 122. In addition, in the fixing hole 115 of the base member 103 for adjusting a temperature, the power feeding terminal 116 of which the outer periphery is surrounded by an insulating material 123 is fixed through the insulating material 123. The power feeding terminal 116 is connected to an external direct current power supply 124.

A material forming the base member 103 for adjusting a temperature is not particularly limited as long as it is a metal having excellent thermal conductivity, electrical conductivity, and workability or a compound material including the metal. As the material for forming the base member 103 for adjusting a temperature, for example, aluminum (Al), copper (Cu), stainless steel (SUS), or titanium (Ti) is preferably used.

It is preferable that at least a surface of the base member 103 for adjusting a temperature that is exposed to a plasma undergoes an alumite treatment or is coated with a resin such as a polyimide resin. In addition, it is more preferable that the entire surface of the base member 103 for adjusting a temperature undergoes an alumite treatment or is coated with a resin.

The base member 103 for adjusting a temperature undergoes an alumite treatment or is coated with a resin such that plasma resistance of the base member 103 for adjusting a temperature is improved and abnormal discharge is prevented. Accordingly, the plasma stability of the base member 103 for adjusting a temperature can be improved, and surface scratches of the base member 103 for adjusting a temperature can also be prevented.

### [Adhesive Layer]

The adhesive layer 104 is configured to bond and integrate the electrostatic chuck member 102 and the base member 103 for adjusting a temperature.

The thickness of the adhesive layer 104 is preferably 100 μm or more and 200 μm or less and more preferably 130 μm or more and 170 μm or less.

When the thickness of the adhesive layer 104 is in the above-described range, the adhesion strength between the electrostatic chuck member 102 and the base member 103 for adjusting a temperature can be sufficiently secured. In addition, the thermal conductivity between the electrostatic chuck member 102 and the base member 103 for adjusting a temperature can be sufficiently secured.

A material of the adhesive layer 104 is formed of, for example, a cured product obtained by thermally curing a silicone resin composition, an acrylic resin, or an epoxy resin.

The silicone resin composition is a silicon compound having a siloxane bond (Si—O—Si) and is a resin having excellent heat resistance and elasticity, which is more preferable.

As the silicone resin composition, in particular, a silicone resin having a thermal curing temperature of 70° C. to 140° C. is preferable.

Here, it is not preferable that the thermal curing temperature is lower than 70° C. because, when the electrostatic chuck member 102 and the base member 103 for adjusting a temperature are joined in a state where they face each other, curing does not progress sufficiently in the process of joining such that the workability deteriorates. On the other hand, it is not preferable that the thermal curing temperature is higher than 140° C. because a difference in thermal expansion between the electrostatic chuck member 102 and the base member 103 for adjusting a temperature is large and stress between the electrostatic chuck member 102 and the base member 103 for adjusting a temperature increases, which may cause peeling therebetween.

That is, it is preferable that the thermal curing temperature is 70° C. or higher because the workability in the process of joining is excellent, and it is preferable that the thermal curing temperature is 140° C. or lower because the electrostatic chuck member 102 and the base member 103 for adjusting a temperature are not likely to peel off from each other.

In the electrostatic chuck device 100 according to the embodiment, the electrostatic chuck member 102 is formed of the ceramic joined body 1. Therefore, in the electrostatic chuck member 102, the occurrence of breakdown (discharge) can be suppressed.

Hereinafter, a method for producing the electrostatic chuck device according to the embodiment will be described.

The electrostatic chuck member 102 formed of the ceramic joined body 1 obtained as described above is prepared.

An adhesive formed of a silicone resin composition is applied to a predetermined region of one main surface 103a of the base member 103 for adjusting a temperature. Here, the amount of the adhesive applied is adjusted such that the electrostatic chuck member 102 and the base member 103 for adjusting a temperature can be joined and integrated.

Examples of a method for applying the adhesive include a method for manually applying the organic adhesive with a spatula, a bar coating method, and a screen printing method.

After applying the adhesive to the main surface 103a of the base member 103 for adjusting a temperature, the electrostatic chuck member 102 and the base member 103 for adjusting a temperature to which the adhesive is applied are laminated.

In addition, the formed power feeding terminal 116 is inserted into the fixing hole 115 that penetrates the base member 103 for adjusting a temperature.

Next, the electrostatic chuck member 102 is pressed against the base member 103 for adjusting a temperature at a predetermined pressure such that the electrostatic chuck member 102 and the base member 103 for adjusting a temperature are joined and integrated. As a result, the electrostatic chuck member 102 and the base member 103 for adjusting a temperature are joined and integrated through the adhesive layer 104.

As a result, the electrostatic chuck device 100 according to the embodiment where the electrostatic chuck member 102 and the base member 103 for adjusting a temperature are joined and integrated through the adhesive layer 104 can be obtained.

The plate-shaped sample according to the embodiment is not limited to a semiconductor wafer and may be, for example, a glass substrate for a flat panel display (FPD) such as a liquid crystal display (LCD), a plasma display (PDP), or an organic EL display. In addition, the electrostatic chuck device according to the embodiment may be designed according to the shape or size of the substrate.

The present invention also includes the following aspects.
[1-1] A ceramic joined body including:
a pair of ceramic plates;
an electrode layer that is interposed between the pair of ceramic plates; and
an insulating layer that is disposed in a periphery of the electrode layer between the pair of ceramic plates,
in which each of the pair of ceramic plates is formed of an insulating material and a conductive material,
the insulating layer is formed of an insulating material and a conductive material, and
the electrode layer is formed of a sintered compact of particles of a conductive material or a sintered compact of particles of an insulating ceramic and particles of a conductive material.
[1-2] The ceramic joined body according to [1-1],
in which materials of the pair of ceramic plates are the same as each other.
[1-3] The ceramic joined body according to [1-2],
in which a relative density of the outer edge of the electrode layer obtained using the following method is lower than a relative density of a center of the electrode layer.

### (Method of Measuring Relative Density)

In a cut surface of the ceramic joined body in the thickness direction, a range of 150 μm from an end portion of the outer edge of the electrode layer toward the inner side of the electrode layer is imaged at a magnification of 1000-fold to obtain a microscope image. A ratio of the area of a region where the material is present to the area of a portion within an outer contour of the electrode layer in the range is obtained as the relative density of the outer edge of the electrode layer.

In the cut surface, a range having a width of 150 μm that includes a center of the electrode layer is imaged at a magnification of 1000-fold to obtain a microscope image. A ratio of the area of a region where the material is present to the area of a portion within an outer contour of the electrode layer in the range is obtained as the relative density of the center of the electrode layer.
[2-1] A ceramic joined body including:
a pair of ceramic plates;
an electrode layer that is interposed between the pair of ceramic plates; and
an insulating layer that is disposed in a periphery of the electrode layer between the pair of ceramic plates,
in which each of the pair of ceramic plates is formed of an insulating material and a conductive material,
the insulating layer is formed of an insulating material and a conductive material and is integrated with one of the pair of the ceramic plates, and
the electrode layer is formed of a sintered compact of particles of a conductive material or a sintered compact of particles of an insulating ceramic and particles of a conductive material.
[2-2] The ceramic joined body according to [2-1],
in which materials of the pair of ceramic plates are the same as each other.
[2-3] The ceramic joined body according to [2-2],
in which a relative density of the outer edge of the electrode layer obtained using the following method is lower than a relative density of a center of the electrode layer.

### (Method of Measuring Relative Density)

In a cut surface of the ceramic joined body in the thickness direction, a range of 150 μm from an end portion of the outer edge of the electrode layer toward the inner side of the electrode layer is imaged at a magnification of 1000-fold to obtain a microscope image. A ratio of the area of a region where the material is present to the area of a portion within an outer contour of the electrode layer in the range is obtained as the relative density of the outer edge of the electrode layer.

In the cut surface, a range having a width of 150 μm that includes a center of the electrode layer is imaged at a magnification of 1000-fold to obtain a microscope image. A ratio of the area of a region where the material is present to the area of a portion within an outer contour of the electrode layer in the range is obtained as the relative density of the center of the electrode layer.

### EXAMPLES

Hereinafter, the present invention will be described in detail using Examples and Comparative Examples, but is not limited to the following examples.

### Example 1

Mixed powder including 91% by mass of aluminum oxide powder (particles) and 9% by mass of silicon carbide powder (particles) was molded and sintered. As a result, a ceramic plate (the first ceramic plate, the second ceramic plate) formed of an aluminum oxide-silicon carbide composite sintered compact having a disk shape with a diameter of 450 mm and a thickness of 5.0 mm was prepared.

Next, using a screen printing method, a paste for forming an electrode layer including a conductive material was applied to one surface of the first ceramic plate to form an electrode layer coating film.

As the paste for forming an electrode layer, a dispersion liquid in which aluminum oxide powder and molybdenum carbide powder were dispersed in isopropyl alcohol was used. In the paste for forming an electrode layer, the content of the aluminum oxide powder was 25% by mass, and the content of the molybdenum carbide powder was 25% by mass.

Next, using a screen printing method, a paste for forming an insulating layer including an insulating material and a conductive material was applied to the one surface of the first ceramic plate to form an insulating layer coating film.

As the paste for forming an insulating layer, a dispersion liquid in which aluminum oxide powder and silicon carbide powder were dispersed in isopropyl alcohol was used. In the paste for forming an insulating layer, the content of the aluminum oxide powder was 55% by mass, and the content of the silicon carbide powder was 5% by mass.

Next, the first ceramic plate was laminated on the joint surface of the second ceramic plate in a posture in which the surface where the electrode layer coating film and the insulating layer coating film were formed faced inward.

Next, a laminate including the first ceramic plate, the electrode layer coating film, the insulating layer coating film, and the second ceramic plate was pressurized in a thickness direction while being heated in an argon atmosphere. The heat treatment temperature was 1700° C., the welding pressure was 10 MPa, and the time for which the heat treatment and the pressurization were performed was 2 hours.

Through the above-described steps, a ceramic joined body according to Example 1 shown in FIG. 1 was obtained.

### (Insulating Characteristics Evaluation)

The insulating characteristics of the ceramic joined body were evaluated as described below.

On a side surface of the ceramic joined body (side surface of the ceramic joined body in the thickness direction), a carbon tape was bonded in a posture in contact with the first ceramic plate, the insulating layer, and the second ceramic plate.

A through electrode that penetrated the first ceramic plate in the thickness direction and reached the electrode layer from the surface of the first ceramic plate opposite to the surface in contact with the electrode layer was formed.

A voltage was applied to the ceramic joined body through the carbon tape and the through electrode, and a voltage at which breakdown occurred in the ceramic joined body was measured. Specifically, an RF voltage was applied in a state where a voltage of 3000 V was applied, and this state was maintained for 10 minutes. Next, a voltage of 500 V was gradually applied, and this state was maintained for 10 minutes. When the measured current value exceeded 0.1 mA (milliampere), breakdown occurred. The results are shown in Table 1.

### Comparative Example

A ceramic joined body according to Comparative Example was obtained using the same method as that of Example 1, except that a paste for forming an insulating layer including only the insulating material is applied to form an insulating layer coating film.

The insulating characteristics of the ceramic joined body were evaluated using the same method as that of Example 1. The results are shown in Table 1.

TABLE 1

| | Example 1 | Comparative Example |
|---|---|---|
| Withstand Voltage | 29.3 | 18.3 |
| (Side Surface) | | |
| (kV/mm) | | |

It was found from the result of Table 1 that the breakdown voltage of the ceramic joined body according to Example 1 was higher than that of the ceramic joined body according to Comparative Example.

### Example 2

One surface (joint surface with the second ceramic plate) of the first ceramic plate was ground, and a recess portion having an inclined surface that was inclined with respect to the thickness direction of the first ceramic plate was formed in the one surface of the first ceramic plate. An opening diameter of the formed recess portion decreased in the thickness direction of the first ceramic plate.

Using a screen printing method, a paste for forming an electrode layer was applied to the recess portion of the first ceramic plate where the recess portion was formed to form an electrode layer coating film. As the paste for forming an electrode layer, the same paste as that of Example 1 was used.

The thickness of the electrode layer coating film was adjusted to be 80% the depth at a deepest portion of the recess portion, and the thickness of the electrode layer coating film in the other portions was adjusted by aligning the height position thereof with the surface of the electrode layer coating film at the deepest portion of the recess portion.

When one surface of the first ceramic plate is set as a reference surface and a perpendicular line is drawn from the reference surface to the bottom of the recess portion, “the depth of the recess portion” refers to the distance from the reference surface to the bottom of the recess portion.

Next, the second ceramic plate was laminated on the one surface of the first ceramic plate in a posture in which the surface where the electrode layer coating film was formed faced inward.

Next, a laminate including the first ceramic plate, the electrode layer coating film, the insulating layer coating film, and the second ceramic plate was pressurized in the thickness direction while being heated in an argon atmosphere. The heat treatment temperature was 1700° C., the welding pressure was 10 MPa, and the time for which the heat treatment and the pressurization were performed was 2 hours.

Through the above-described steps, a ceramic joined body according to Example 2 shown in FIG. 3 was obtained.

### (Density of Electrode Layer)

The density of the electrode layer was obtained using (Method of Measuring Relative Density of Electrode Layer) described above. In the ceramic joined body according to Example 1, the density of an outer edge portion of the electrode layer was substantially 100%.

Each of the evaluation results is shown in Table 2.

TABLE 2

| | Example 2 |
|---|---|
| Density of Outer Edge Portion of Electrode Layer | 80% |
| Withstand Voltage (Side Surface) (kV/mm) | 26.0 |

It was verified that the density of the center of the electrode layer was substantially 100%. It was found from the result of Table 2 that, in the ceramic joined body according to Example 2, the relative density of the outer edge of the electrode layer was lower than that of the ceramic joined body according to Example 1, insulating characteristics equivalent to those of Example 1 were exhibited, and the breakdown voltage was higher than that of the ceramic joined body according to Comparative Example.

In Example 1 and Example 2, the methods of forming the insulating layers were different, but the functions of the insulating layers were common. Therefore, in the configuration of Example 1, it is assumed that even when the outer edge of the electrode layer has a low density as in Example 2, the breakdown voltage is higher than that of the ceramic joined body according to Comparative Example.

### INDUSTRIAL APPLICABILITY

The ceramic joined body according to the present invention includes: a pair of ceramic plates; and an electrode layer and an insulating layer that are interposed between the pair of ceramic plates, in which the insulating layer is formed of an insulating material and a conductive material. Therefore, breakdown (discharge) in a joint interface between the ceramic plate and the insulating layer is suppressed. The ceramic joined body according to the present invention is suitably used for an electrostatic chuck member of an electrostatic chuck device, and the usefulness thereof is significantly high.

### REFERENCE SIGNS LIST

1, 10, 20: ceramic joined body
2: ceramic plate (first ceramic plate)
3: ceramic plate (second ceramic plate)
4: electrode layer
5: insulating layer
100: electrostatic chuck device
102: electrostatic chuck member
103: base member for adjusting temperature
104: adhesive layer
111: placement plate
112: supporting plate
113: electrode for electrostatic adsorption
114: insulating material
115: fixing hole
116: power feeding terminal
117: conductive adhesive layer
118: through hole
121: flow path
122: high frequency power supply
123: insulating material
124: direct current power supply

1. A ceramic joined body comprising:
a pair of ceramic plates;
an electrode layer that is interposed between the pair of ceramic plates; and
an insulating layer that is disposed in a periphery of the electrode layer between the pair of ceramic plates,
wherein the insulating layer is formed of an insulating material and a conductive material.

2. The ceramic joined body according to claim 1,
wherein the insulating layer is a layer which has been integrally formed with one of the pair of ceramic plates.

3. The ceramic joined body according to claim 1,
wherein the insulating material is at least one selected from a group consisting of Al₂O₃, AlN, Si₃N₄, Y₂O₃, YAG, SmAlO₃, MgO, and SiO₂.

4. The ceramic joined body according to claim 1,
wherein the conductive material is at least one selected from a group consisting of SiC, TiO₂, TiN, TIC, W, WC, Mo, Mo₂C, and C.

5. The ceramic joined body according to claim 1,
wherein a relative density of an outer edge of the electrode layer is lower than a relative density of a center of the electrode layer.

6. The ceramic joined body according to claim 1,
wherein materials of the pair of ceramic plates are the same as each other.

7. The ceramic joined body according to claim 1,
wherein the pair of ceramic plates are formed of an insulating material and a conductive material.

8. An electrostatic chuck device,
wherein an electrostatic chuck member, which is formed of a ceramic, and a base member for adjusting a temperature, which is formed of a metal, are joined through an adhesive layer, and
the electrostatic chuck member is formed of the ceramic joined body according to claim 1.
